(19) United States
(12) Patent Application Publication
(10) Pub. No.: US 2005/0081781 A1
(43) Pub. Date: Apr. 21, 2005

(54) Fully dry, Si recess free process for removing high k dielectric layer

(75) Inventors: Huan-Just Lin, Hsin-Chu (TW); Ming-Huan Tsai, Hsinchu (TW); Li-Te S. Lin, Hsin-Chu (TW); Yuan-Hung Chiu, Taipei (TW); Han-Jan Tao, Hsinchu (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co.

(21) Appl. No.: 10/688,045

(22) Filed: Oct. 17, 2003

(51) Int. Cl. C30B 23/00; C30B 25/00; C30B 28/12; C30B 28/14

(52) U.S. Cl. 117/104

(57) ABSTRACT

A fully dry etch method is described for removing a high k dielectric layer from a substrate without damaging the substrate and has a high selectivity with respect to a gate layer. The etch is comprised of BCl₃, a fluorocarbon, and an inert gas. A low RF bias power is preferred. The method can also be used to remove an interfacial layer between the substrate and the high k dielectric layer. A HfO₂ etch rate of 55 Angstroms per minute is achieved without causing a recess in a silicon substrate and with an etch selectivity to polysilicon of greater than 10:1. Better STI oxide divot control is also provided by this method. The etch through the high k dielectric layer may be performed in the same etch chamber as the etch process to form a gate electrode.

### RELATED PATENT APPLICATIONS

This application is related to the following: Docket #TSMC02-0405, Ser. No. ______, filing date ______ and Docket #TSMC01-1248, Ser. No. 10/653,852, filing date Sep. 3, 2003; both assigned to a common assignee.

### FIELD OF THE INVENTION

The invention relates to a method of fabricating semiconductor devices. More particularly, the present invention is a method of selectively removing a high k dielectric layer from a substrate without causing a thickness loss in adjacent substrate regions or in a shallow trench oxide layer.

### BACKGROUND OF THE INVENTION

As the gate length in transistors shrinks in order to keep pace with demands for improved performance, the thickness of the gate electrode and the gate dielectric layer are following a trend toward thinner films. Shrinking device dimensions force a thinner gate dielectric layer in order to maintain an adequate capacitance between the gate electrode and the channel region. A traditional gate dielectric layer consisting of silicon oxide with a dielectric constant (k) of about 4 is being replaced by a high k dielectric layer with a k value of 10 or greater in order to reduce gate leakage current associated with an ultra thin SiO₂ layer. A high k dielectric layer has an electrically equivalent thickness to a thinner SiO₂ layer. For example, HfO₂ with a k value of about 40 has an equivalent oxide thickness (EOT) that is 1/10 of its physical thickness. Therefore, a sufficient gate dielectric layer thickness can be maintained as a barrier to prevent dopant from migrating between a channel region and a gate electrode layer without compromising the electrical property of the gate dielectric layer. High k dielectric materials such as ZrO₂, HfO₂, TiO₂, Al₂O₃, Y₂O₃, La₂O₅ and Ta₂O₅ as well as their aluminates and silicates provide a path to scaling the EOT to less than 2 Angstroms for advanced technologies. HfO₂ is especially attractive as a high k gate dielectric material because it demonstrates good device characteristics and is compatible with a polysilicon gate process.

In some cases, an ultra thin interfacial layer of less than 10 Angstroms consisting of SiO₂, silicon nitride or silicon oxynitride is formed on the substrate before depositing the high k dielectric layer. The interfacial layer is used to passivate dangling bonds on the substrate surface and to prevent charge/traps in the high k dielectric layer from contacting the channel region. In U.S. Pat. No. 6,258,675, a silicon nitride interfacial layer is used both above and below a high K dielectric layer. However, no details are given for the etch process that selectively removes the high k dielectric layer.

One concern with a high k gate dielectric layer comprised of HfO₂ is that it is not easily removed from substrate regions that will be implanted with dopant to generate source/drain (S/D) regions. Conventional plasma etch methods do not provide a high enough selectively relative to SiO₂ above isolation regions or to silicon above S/D regions in the substrate. Furthermore, Hf does not easily form volatile by-products when etched with a plasma based on Cl, Br, or F containing gases. The resulting Hf residues are difficult to remove and may contaminate the final device. A high sputtering component to the high k etch may be used but this method also etches silicon and causes a severe recess in the substrate adjacent to the high k dielectric layer. Another option for high k material removal is a combination of a plasma etch and a wet etch. However, this arrangement is not preferred since it complicates process flow, adds to production cost, and attacks oxide in STI features.

U.S. Pat. No. 6,306,715 describes a method for isotropically etching a metal oxide such as HfO₂. A combination of SF₆, Cl₂, and O₂ or a mixture of Cl₂ and O₂ is used to create an undercut profile beneath a gate to allow for angled ion implant and to prevent polybridging.

A high k dielectric layer which is Ta₂O₅, CuO₂, A1₂O₃ or TiO₂ is formed as part of a metal-oxide-metal capacitor in U.S. Pat. No. 6,492,242. A preferred method for etching the high k material is based on a BF₃ or CF₄/CHF₃ chemistry.

In U.S. Pat. No. 6,479,403, a high k dielectric layer is deposited on a partially formed transistor structure and is preferably etched with an argon sputter method. Optionally, O₂ and C_{X}F_{y}, C_{X}H_{Y}F_{Z}, or C_{X}F_{Y} where x and y are integers are also included in the argon sputter process. Unfortunately, a sputter method has a tendency to damage the substrate by forming a recess next to the high k dielectric layer.

A method is described in U.S. Pat. No. 6,451,647 for removing a high k dielectric layer and includes a plasma etch comprised of a fluorocarbon, O₂, and an inert gas. A second etch may be performed by employing the same chemistry at low power to remove residues from the high k dielectric layer. However, any etch process based on a fluorocarbon/O₂ chemistry is likely to produce an undesirable recess in the silicon substrate.

An etch chemistry comprised of BCl₃, an inert gas, and optionally O₂, N₂, or Cl₂ is used to selectively etch a ferroelectric layer such as PZT or BST in the presence of SiO₂ in U.S. Pat. No. 6,436,838. A TiO₂ high k dielectric layer is listed as an optional etch mask for this etch chemistry and therefore has a low removal rate.

Therefore, an improved method for removing a high k gate dielectric layer from a substrate is needed. The method should not damage the oxide layer in an adjacent shallow trench isolation feature and should not harm the substrate. A high selectivity of the high k gate dielectric layer to the gate layer during the removal step is desirable. Additionally, a one step removal method that is a fully dry process is needed to provide high product throughput in a cost effective manner.

### SUMMARY OF INVENTION

One objective of the present invention is to provide a method of removing a high k gate dielectric layer from a substrate that does not remove oxide from an adjacent STI feature and does not form a recess in the substrate adjacent to the high k gate dielectric layer.

A further objective of the present invention is to provide an etch method for removing a high k gate dielectric layer in a partially formed transistor that has a high selectivity for HfO₂ relative to a polysilicon gate layer.

Still another objective is to provide a method for removing a high k gate dielectric layer from a substrate that is a fully dry process which is cost effective.

These objectives are achieved in one embodiment by providing a substrate having a partially formed transistor comprised of a gate layer on a gate dielectric layer that is formed on an active region between STI features. The gate dielectric layer is a high k dielectric material which is preferably HfO₂ but may also be selected from a group that includes ZrO₂, TiO₂, Ta₂O₅, La₂O₅, Y₂O₃, and Al₂O₃. Optionally, the gate dielectric layer may be a composite layer that includes HfO₂ and one or more of the aforementioned oxides. Still another option is that the dielectric layer is a silicate, nitride, or oxynitride of Hf, Zr, Ti, Ta, La, Y, or Al.

After the gate layer is patterned to form a gate electrode, a plasma etch process that is key to the invention is performed to remove the high k dielectric layer in exposed regions. The etch process is preferably comprised of a low bias power and is based on a gas mixture that includes BCl₃, C_{X}H_{Y}F_{Z}, and an inert gas. The etch process removes the high k dielectric layer without forming a recessed substrate or causing an oxide loss in STI features. When HfO₂ is employed as the high k gate dielectric layer, the reaction between BCl₃ and HfO₂ produces volatile products including HfCl₄. Optionally, a cleaning step may be inserted after etching the high k gate dielectric layer. The resulting partially formed transistor is then processed by conventional steps that typically form sidewall spacers on the gate electrode and source/drain regions in the substrate.

In a second embodiment, an interfacial layer is formed on the substrate prior to deposition of a high k gate dielectric layer and a gate layer. The interfacial layer is preferably less than 10 Angstroms thick and is comprised of SiO₂, silicon nitride, or silicon oxynitride. The gate electrode is formed in the gate layer as described in the first embodiment. A spacer is formed adjacent to each side of the gate electrode by depositing a layer of silicon nitride or SiO₂ and then etching back the nitride or oxide layer. A plasma etch with low bias power is performed to remove exposed regions of the high k dielectric layer and is based on a gas mixture of BCl₃, C_{X}H_{Y}F_{Z}, and an inert gas. The etch process is continued after the high k dielectric layer is removed and also etches the interfacial layer but stops on the silicon substrate without causing a recess in the substrate or loss of oxide. The gate layer etch and the high k dielectric etch steps are preferably accomplished in the same etch chamber.

### BRIEF DESCRIPTION OF THE DRAWINGS

FIGS. 1a-1c are cross-sectional views showing a prior art method of etching a high k dielectric layer on a substrate that leaves a recess in the substrate or in a STI feature.

FIG. 2 is a cross-sectional view that depicts a photoresist pattern on a gate layer in a partially formed transistor according to the first embodiment of the present invention.

FIG. 3 is a cross-sectional view that shows the etch transfer of the pattern in FIG. 2 through the gate layer according to a method of the first embodiment.

FIG. 4 is a cross-sectional view of the structure in FIG. 3 after the photoresist and ARC are stripped and following removal of the exposed regions of a high k dielectric layer according to a plasma etch method of the first embodiment.

FIGS. 5-9 are cross-sectional views that depict a method of processing a high k dielectric layer on a partially formed transistor according to the second embodiment of the present invention.

### DETAILED DESCRIPTION OF THE INVENTION

The present invention is a method of removing a high k dielectric layer from a substrate. Although a description is provided with regard to a high k gate dielectric layer on a substrate in a partially formed metal oxide semiconductor field effect transistor (MOSFET) which may be a p-type (PMOS) or n-type (NMOS) transistor, the substrate with a high k dielectric layer formed thereon may be used to fabricate other semiconductor devices including capacitors. The drawings are not intended to limit the scope of the invention and the figures are not necessarily drawn to scale.

Referring to FIGS. 1a-1c, a method of etching a high k dielectric layer that has been previously practiced by the inventors is illustrated. In FIG. 1a, a substrate 10 is provided that has shallow trench isolation (STI) features 11 which define an active region 14. A high k dielectric layer 12 that is HfO₂ is deposited on substrate 10 and a gate electrode 13 is formed by a conventional method that involves patterning a photoresist layer (not shown) on the gate electrode 13 and using the photoresist as a mask while transferring the pattern through the gate electrode 13. In FIG. 1b, exposed regions of high k dielectric layer 12 are removed by a plasma etch that is generated from a gas mixture that includes a fluorocarbon, O₂, and Ar. The etch also attacks substrate 10 in active region 14 adjacent to the gate electrode 13 and forms a recess 15 having a depth d of several Angstroms. This recess 15 is frequently large enough to detract from device performance. FIG. 1c shows the result of a HfO₂ removal process that includes a combination of a dry etch followed by a wet etch. In this case, a recess in substrate 10 is avoided but the wet etch attacks the STI feature 11 and a thickness loss t occurs that will have a detrimental impact on device performance.

In related art, an etch method for a high k dielectric layer in application TSMC02-405, Ser. No. ______, filing date ______,is herein incorporated by reference.

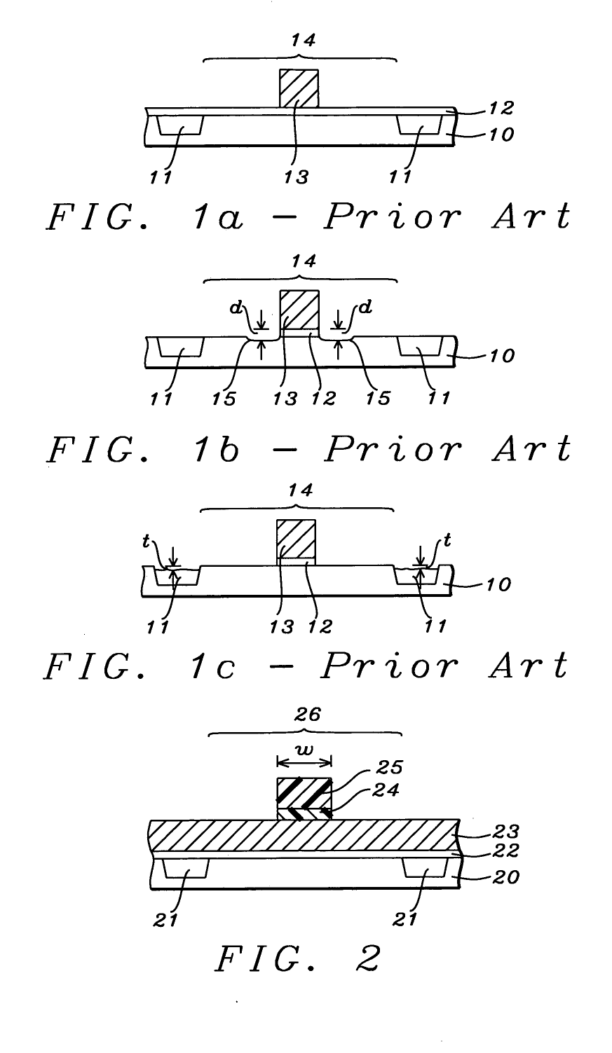

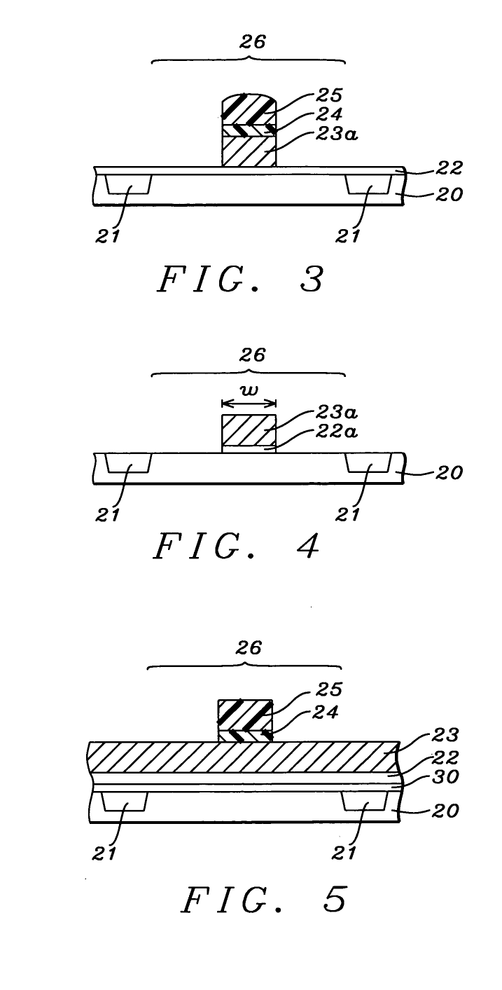

The first embodiment is depicted in FIGS. 2-4. Referring to FIG. 2, a substrate 20 is provided which typically contains active and passive devices that are not shown in order to simplify the drawing. Substrate 20 may also contain n and p wells (not shown). Shallow trench isolation (STI) features 21 are formed in the substrate 20 by conventional methods and typically are comprised of a liner on the sidewalls and bottom of the trenches and SiO₂ or a low k dielectric layer formed on the liner. STI features 21 may be coplanar with substrate 20 or have a top surface that is slightly above substrate 20. An active region 26 is defined as the portion of substrate 20 between the STI features 21. A MOSFET will be fabricated in the active region 26. In one embodiment, a thin interfacial layer (not shown) comprised of SiO₂, silicon nitride, or silicon oxynitride having a thickness of less than about 10 Angstroms is deposited on the substrate 20 and on STI features 21 by a CVD technique.

A high k dielectric layer 22 having a thickness between about 15 and 100 Angstroms is deposited on the substrate 20 or optionally on a thin interfacial layer by a chemical vapor deposition (CVD), metal organic CVD, or atomic layer deposition (ALD) process. A high k dielectric layer is intended to mean a dielectric layer having a dielectric constant (k) of about 10 or larger. In one embodiment, the high k dielectric layer 22 is preferably HfO₂ but also may be ZrO₂, Ta₂O₅, TiO₂, Al₂O₃, Y₂O₃ or La₂O₅. In another embodiment, the high k dielectric layer 22 is formed by an ALD technique and is a composite layer of HfO₂ and one or more of the aforementioned metal oxides. An exemplary ALD method for forming a composite layer of HfO₂ and ZrO₂ in application TS01-1248, Ser. No. 10/653,852, filing date Sep. 3, 2003 is herein incorporated by reference. It is understood by those skilled in the art that other metal oxide composite layers can be formed by this ALD method. In another embodiment, the composite layer comprised of HfO₂ and one or more of the aforementioned metal oxides is formed by simultaneously depositing two or more metal oxides in a CVD or ALD process. However, the ALD technique is preferred since it provides a more controlled composition and better uniformity in the high k dielectric layer 22.

Optionally, the high k dielectric layer 22 is comprised of a silicate, aluminate, nitride, or oxynitride of hafnium or a binary or ternary metal oxide. The high k dielectric layer 22 may be formed by a surface treatment known to those skilled in the art on a layer comprised of one of the aforementioned high k dielectric materials. Preferably, the CVD or ALD step of a high k dielectric layer 22 is followed by an anneal comprised of heating the substrate in an O₂ or H₂ ambient at about 800° C. for approximately 20 minutes.

Next, a gate layer 23 having a thickness from about 500 to 1500 Angstroms is deposited on the high k dielectric layer 22 by a physical vapor deposition (PVD), CVD, or plasma enhanced CVD process. Alternatively, a rapid thermal CVD, metal organic CVD, or atomic layer CVD process may be carried out in a single wafer cluster tool. The gate layer 23 is preferably polysilicon but may also be silicon-germanium, or amorphous silicon. The gate layer 23 may be doped or undoped. In another embodiment, the gate layer 23 is comprised of a metal or a metal containing compound such as W, Ta, Al, Ni, Ru, Pd, Pt, Ti, Mo, TiN, TaN, TaSiN, or the like.

Because the gate layer 23 has a high reflectivity, an anti-reflective coating (ARC) 24 is typically coated on the gate layer to improve process latitude in a subsequent lithographic process. The ARC 24 may be an organic film that is spin coated and baked at temperatures up to about 250° C. to cure the film and remove residual solvent or the ARC 24 is an inorganic layer such as silicon oxynitride that is formed by a CVD or plasma enhanced CVD method. Note that the ARC 24 is selected with an appropriate refractive index (n and k values) to minimize reflections off the gate layer 23 during subsequent patterning of a photoresist layer 25.

A commercially available photoresist solution is coated and baked on the ARC 24 to form photoresist layer 25. The photoresist layer 25 is patterned by a conventional lithography process involving one or more exposure wavelengths in the range of about 10 nm to 600 nm to generate a photoresist layer 25 comprised of a line having a width w. A plasma etch that generally includes oxygen and an inert gas is employed to remove the ARC 24 exposed by patterned photoresist layer 25. In one embodiment, photoresist layer 25 has a width w that is less than 100 nm and is the minimum width which can be printed by state of the art exposure tools. In another embodiment, a width w that is smaller than the minimum width achieved by a lithography step is generated in the photoresist layer 25 and ARC 24 by performing one etch step that transfers the pattern through the ARC 24 and a second etch step that laterally trims the patterned photoresist layer 25 and ARC 24.

The exposed portion of the gate layer 23 is then etched by a conventional method that typically involves a halogen gas. For example, a plasma generated from a Cl₂ and HBr gas mixture or a Cl₂/HBr/O₂ chemistry is effective in etching a polysilicon layer. Preferably, an anisotropic etch transfers the pattern in the photoresist layer 25 into the gate layer 23 to form a gate electrode 23a having a width w. Some of the photoresist mask 25 is likely to be consumed during the etch to form gate electrode 23a. Any remaining photoresist layer 25 and ARC 24 are stripped by an organic solution or by an oxygen ashing method known to those skilled in the art.

Referring to FIG. 4, a key feature of the invention is an etch process to remove the high k dielectric layer 22 that is exposed during formation of the gate electrode 23a. As a result, a trimmed gate dielectric layer 22a is formed and has a width w. The etch process is not restricted to a particular type of etch chamber and the plasma may be generated by various means including a capacitive method with parallel plate electrodes, an inductive method, or with a microwave source. The inventors have discovered that a gas combination which includes BCl₃, an inert gas such as Ar, He, Ne, or Xe, and one or more fluorocarbon (C_{X}H_{Y}F_{Z}) gases where x an z are integers and y is an integer or is 0 is especially effective in forming a plasma in an etch chamber that will remove a high k dielectric layer without forming high k dielectric residues or damaging the substrate 20 or STI features 21. Optionally, CH₄ by itself or in combination with a C_{X}H_{Y}F_{Z} gas may be employed. In one embodiment, the C_{X}H_{Y}F_{Z} gas is one or more of CF₄, CHF₃, CH₂F₂, CH₃F, C₂HF₅, C₂H₂F₄, and C₂F₆. Preferably, the etch through the high k dielectric layer 22 is accomplished in the same chamber used to etch the gate layer 23 and form a gate electrode 23a in the previous step. When a HfO₂ high k dielectric layer 22 is etched with a plasma that includes BCl₃ as the main etchant, the products of the reaction are believed to be B(OCl)₃ and HfCl₄ which are both gases and are expelled through an exit port in the etch chamber.

Preferred process conditions are a BCl₃ gas flow rate of from 100 to 400 standard cubic centimeters per minute (sccm), an inert gas flow rate of from 100 to 500 sccm, a C_{X}H_{Y}F_{Z} gas flow rate of 5 to 20 sccm, a chamber pressure of between 5 and 20 mTorr, a RF power of from 200 to 800 Watts, a RF bias power of between 10 and 50 Watts, and a substrate temperature of between 50° C. and 70° C. Although the etch may be accomplished without a bias power, a low bias power is preferred. The etch is performed until an end point is detected by a drop in the OES signal for a metal in the high k dielectric layer as is well known to those who practice the art. Optionally, the etch is carried out for a predetermined period of time that ranges from about 60 to 90 seconds. By utilizing these conditions, an HfO₂ etch rate of about 60 to 120 Angstroms per minute is achieved. Note that the bias power is generally applied from the bottom of the process chamber and improves the etch rate of the high k dielectric layer 22. A low bias power minimizes the sputter component of the etch and thereby avoids damage to the substrate 20 and to STI features 21.

After the etch process through the high k dielectric layer 22 is complete, a wet clean step comprising a dilute HF dip for about 30 to 60 seconds is performed. The dilute HF consists of one part HF and 100 to 1000 parts deionized H₂O. The partially formed transistor comprising the active region 26, gate electrode 23a, and gate dielectric layer 22a is ready for further processing which typically includes forming source/drain (S/D) regions in the substrate and forming sidewall spacers on the gate electrode and high k dielectric layer which are not shown since these details are not pertinent to the present invention and are well known to those skilled in the art.

In a second embodiment depicted in FIGS. 5-7, a substrate 20 having STI features 21 is provided as described in the first embodiment. Referring to FIG. 5, a thin interfacial layer 30 with a thickness between about 1 and 30 Angstroms and preferably less than 10 Angstroms is deposited on the substrate 20 and is a material such as SiO₂, silicon nitride or silicon oxynitride. The interfacial layer 30 is preferably formed by a rapid thermal process (RTP) although a low pressure CVD or plasma enhanced CVD process can also be used for the deposition. The interfacial layer 30 is usually employed to passivate dangling bonds in substrate 20 and to prevent an interaction between the high k dielectric layer 22 and the active region 26 in substrate 20. Alternatively, the interfacial layer 30 may be omitted in the second embodiment.

A high k dielectric layer 22 having a thickness between about 15 and 100 Angstroms is deposited on interfacial layer 30 by a chemical vapor deposition (CVD), metal organic CVD, or atomic layer deposition (ALD) process. In one embodiment, the high k dielectric layer 22 has a k value of about 10 or larger and is preferably HfO₂ but also may be ZrO₂, Ta₂O₅, TiO₂, Al₂O₃, Y₂O₃ or La₂O₅. In another embodiment, the high k dielectric layer 22 is formed by an ALD technique as mentioned in the first embodiment and is a composite layer of HfO₂ and one or more of the aforementioned metal oxides. In another embodiment, the composite layer comprised of HfO₂ and one or two of the aforementioned metal oxides is formed by simultaneously depositing two or more metal oxides in a CVD process. Optionally, the high k dielectric layer 22 is comprised of a silicate, aluminate, nitride, or oxynitride of hafnium or is a binary or ternary metal oxide having a k value of greater than 15. The formation of the high k dielectric layer 22 may be further comprised of a surface treatment following the deposition of one of the aforementioned high k dielectric materials. Preferably, the deposition of the high k dielectric layer 22 is followed by an anneal comprised of heating the substrate in an O₂ or H₂ ambient at about 800° C. for approximately 20 minutes. 13.

Next, a gate layer 23 having a thickness from 500 to 1500 Angstroms is deposited on high k dielectric layer 22 by a PVD, CVD, or plasma enhanced CVD process. Alternatively, a rapid thermal CVD, metal organic CVD, or atomic layer CVD process may be carried out in a single wafer cluster tool to deposit the gate layer. The gate layer 23 is preferably polysilicon but may also be silicon-germanium, or amorphous silicon. The gate layer 23 may be doped or undoped. In another embodiment, the gate layer 23 is comprised of a metal or a metal containing compound such as W, Ta, Al, Ni, Ru, Pd, Pt, Ti, Mo, TiN, TaN, TaSiN, or the like.

Because gate layer 23 has a high reflectivity, an ARC 24 is typically coated on the gate layer to improve process latitude in a subsequent lithographic process. The ARC 24 is an organic film that is spin coated and baked at temperatures up to about 250° C. to cure the film and remove residual solvent or the ARC 24 is an inorganic layer such as silicon oxynitride that is formed by a CVD or plasma enhanced CVD method. A photoresist is coated on the ARC 24 and is patterned to form a photoresist layer 25 comprised of a line having a linewidth w as described in the first embodiment. The pattern is transferred through the ARC 24 by a plasma etch that typically includes oxygen and an inert gas. Alternatively, a width w that is smaller than the minimum width achieved by a lithography step is generated in the photoresist layer 25 and ARC 24 by performing one etch step that transfers the pattern through the ARC 24 and a second etch step that laterally trims the patterned photoresist layer 25 and ARC 24.

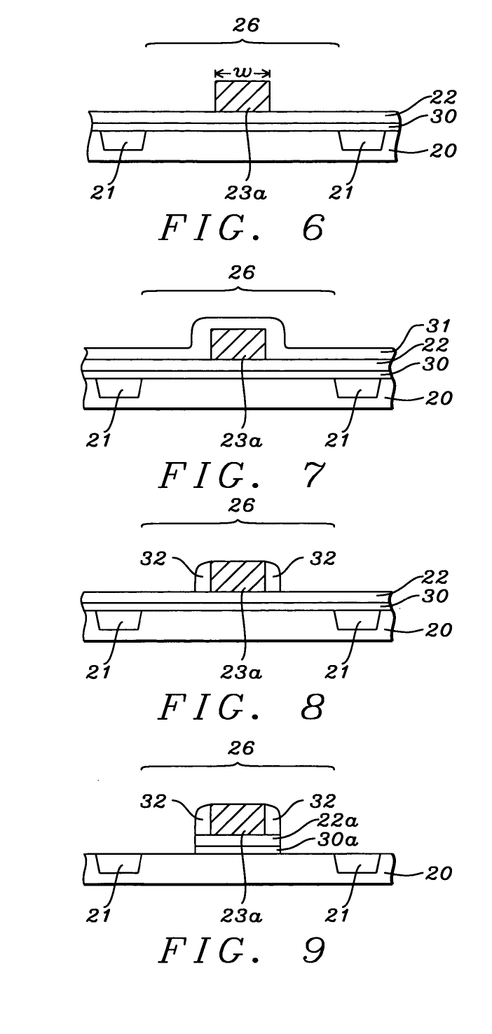

Referring to FIG. 6, a conventional plasma etch step is used to transfer the pattern formed in the photoresist layer 25 and ARC 24 through the gate layer 23 to form a gate electrode 23a having a width w. Any remaining photoresist layer 25 and ARC 24 are stripped by a commercially available organic solution or by an oxygen ashing method. A conventional cleaning step may be performed at this point to ensure that all residues are removed from substrate 20.

Next, a conventional process is followed to form a spacer adjacent to each side of the gate electrode 23a. A CVD process, for example, is carried out to deposit a dielectric layer 31 such as silicon nitride or SiO₂ on gate electrode 23a and on high k dielectric layer 22. The dielectric layer 31 is etched back in a plasma etch with an appropriate gas chemistry known to those skilled in the art so that a spacer 32 is formed on opposite sides of gate electrode 23a. In a preferred embodiment, the spacers 32 are formed in the same process tool in which the gate layer was etched to form the gate electrode 23a. It is understood that a process tool may contain multiple process chambers in which deposition and etching steps may be performed.

Referring to FIG. 7, a key feature of the invention is an etch process to remove portions of the high k dielectric layer 22 that are exposed after the formation of gate electrode 23a and spacers 32. Preferably, the etch process also removes the interfacial layer 30 that is uncovered by removing portions of the high k dielectric layer 22. As a result, a gate dielectric layer 22a and an interfacial layer 30a are formed underlying the spacers 32 and gate electrode 23a. The etch process is not restricted to a particular type of etch chamber and the plasma may be generated by various means including a capacitive method with parallel plate electrodes, an inductive method, or with a microwave source. In a preferred embodiment, the etch through the high k dielectric layer 22 and interfacial layer 30 is accomplished in the same chamber that was used to etch through the gate layer 23 in the previous step.

The inventors have discovered that a gas combination which includes BCl₃, an inert gas such as Ar, He, Ne, or Xe, and one or more fluorocarbon (C_{X}H_{Y}F_{Z}) gases where x and z are integers and y is an integer or is 0 is especially effective in forming a plasma in an etch chamber that will remove the high k dielectric layer 22 without forming high k dielectric residues or damaging substrate 20 or STI features 21. Optionally, CH₄ by itself or in combination with a C_{X}H_{Y}F_{Z} gas may be employed. In one embodiment, the C_{X}H_{Y}F_{Z} gas is one or more of CF₄, CHF₃, CH₂F₂, CH₃F, C₂HF₅, C₂H₂F₄, and C₂F₆.

Preferred process conditions are a BCl₃ gas flow rate of from 100 to 400 standard cubic centimeters per minute (sccm), an inert gas flow rate of from 100 to 500 sccm, a C_{X}H_{Y}F_{Z} gas flow rate of 5 to 20 sccm, a chamber pressure of between 5 and 20 mTorr, a RF power of from 200 to 800 Watts, a RF bias power of between 10 and 50 Watts, and a substrate temperature of between 50° C. and 70° C. Although the etch may be accomplished without a bias power, a low bias power is preferred. The etch is performed until an end point is detected by a drop in the OES signal for a metal in the high k dielectric layer as is well known to those who practice the art. Optionally, the etch is carried out for a predetermined period of time that ranges from about 60 to 90 seconds. By utilizing these conditions, an HfO₂ etch rate of about 60 to 120 Angstroms per minute is achieved. Note that the bias power is generally applied from the bottom of the process chamber and improves the etch rate of the high k dielectric layer 22. A low bias power minimizes the sputter component of the etch and thereby avoids damage to the substrate 20.and to STI features 21.

After the etch process through the high k dielectric layer 22 and the interfacial layer 30 is complete, a wet clean step comprising a dilute HF dip for about 30 to 60 seconds is performed. The dilute HF consists of one part HF and 100 to 1000 parts deionized H₂O. The resulting particle defect count on substrate 20 is quite low and is comparable to the number of particles formed from a conventional high k dielectric etch method that involves CF_{X}/O₂/Ar, for example.

The partially formed transistor comprising the active region 26, interfacial layer 30a, gate electrode 23a, spacers 32, and gate dielectric layer 22a is ready for further processing which typically includes forming source/drain (S/D) regions in the substrate and formation of a silicide layer on the gate electrode and on the S/D regions which are not shown since these details are not pertinent to the present invention and are well known to those skilled in the art.

An advantage of the present invention as exemplified in the first and second embodiments is that damage to the substrate in the form of a recess 15 as shown in a prior art example in FIG. 1b is avoided. For example, a prior art plasma etch chemistry based on a fluorocarbon, oxygen, and an inert gas is known to cause a recess 15 that has a depth d as large as 70 Angstroms. However, when a plasma etch through a high k dielectric layer is performed according to the present invention, no recess is detected in the underlying substrate. When the high k dielectric layer is HfO₂, an etch rate of about 55 Angstroms per minute is achieved which is very similar to the etch rate observed with prior art chemistry. Therefore, a high throughput is maintained. An additional benefit is that the etch rate selectivity of HfO₂ to polysilicon is increased from 3.6:1 for prior art chemistry to greater than 10:1 in the present invention. Thus, undesirable thinning of the gate electrode is greatly reduced during removal of the high k dielectric layer. Furthermore, the fully dry etch process of the present invention does not attack oxide in STI features as in prior art methods that include a wet etch to remove the high k dielectric layer.

The fully dry etch process of the present invention provides a cost savings because devices with higher reliability and higher performance are produced and a higher yield of acceptable product is realized. The fully dry etch process can be implemented on existing tools and simplifies the process flow compared to a high k dielectric removal method that involves a wet etch. Additionally, the high cost associated with solvents in a wet chemical etch is eliminated. It is understood that the etch process of the present invention is applicable to either 200 mm or 300 mm substrates and is not dependent on the size of the gate electrode. However, as the size of the gate electrode shrinks, the advantages of this invention become more apparent.

While this invention has been particularly shown and described with reference to, the preferred embodiment thereof, it will be understood by those skilled in the art that various changes in form and details may be made without departing from the spirit and scope of this invention.

1. A method of removing a high k dielectric layer from a substrate comprising the steps of:
(a) providing a substrate with a high k dielectric layer formed thereon;
(b) depositing a gate layer and forming a gate electrode on said high k dielectric layer that exposes portions of said high k dielectric layer; and
(c) etching through said exposed portions of said high k dielectric layer with a plasma etch comprised of an inert gas, BCl₃, and one or more fluorocarbon gases or CH₄.

2. The method of claim 1 wherein said plasma etch is further comprised of a low bias power of about 10 to 50 Watts.

3. The method of claim 1 wherein said high gate dielectric layer is formed by a chemical vapor deposition (CVD), metal organic CVD (MOCVD), or an atomic layer deposition (ALD) process and has a thickness between about 15 and 100 Angstroms.

4. The method of claim 1 wherein said high k dielectric layer is comprised of one or more of HfO₂, ZrO₂, Ta₂O₅, TiO₂, Al₂O₃, Y₂O₃ or La₂O₅.

5. The method of claim 1 wherein said high k dielectric layer is a silicate, aluminate, nitride, or oxynitride of Hf, Zr, Ta, Ti, Y, or La.

6. The method of claim 1 wherein the high k dielectric layer is subjected to a post-deposition surface treatment or an anneal step prior to forming a gate layer on said high k dielectric layer.

7. The method of claim 6 wherein said anneal step is comprised of heating the substrate in an O₂ or H₂ ambient at about 800° C. for a period of about 20 minutes.

8. The method of claim 1 wherein said gate layer is comprised of polysilicon, amorphous silicon, Si—Ge, W, Ta, Al, Ti, Ni, Ru, Pa, Pt, Mo, TiN, TaN, or TaSiN.

9. The method of claim 1 wherein said gate layer has a thickness between about 500 and 1500 Angstroms.

10. The method of claim 1 wherein said plasma etch is performed with BCl3, an inert gas comprised of Ar, He, Ne, or Xe, and one or more fluorocarbon gases C_{X}H_{Y}F_{Z} where x and z are integers and y is an integer or is 0 including CF₄, CHF₃, CH₂F₂, CH₃F, C₂HF₅, C₂H₂F₄, and C₂F₆.

11. The method of claim 1 wherein said plasma etch is performed with a BCl₃ flow rate of about 100 to 400 standard cubic centimeters per minute (sccm), a fluorocarbon gas flow rate from about 5 to 20 sccm, and an inert gas flow rate between about 100 and 500 sccm.

12. The method of claim 1 wherein said plasma etch is performed with a chamber pressure from about 5 to 20 mTorr and a substrate temperature between about 50° C. and 70° C.

13. The method of claim 1 wherein said plasma etch is performed with a RF power between about 200 and 800 Watts.

14. The method of claim 1 wherein said plasma etch is continued until an end point is reached as indicated by a drop in an OES signal for a metal in the high k dielectric layer or is carried out for a period of about 60 to 90 seconds.

15. The method of claim 1 further comprised of forming an interfacial layer that is SiO₂, silicon nitride, or silicon oxynitride on said substrate prior to forming said high k dielectric layer.

16. The method of claim 15 wherein said interfacial layer is removed during the same plasma etch step that removes the high k dielectric layer.

17. The method of claim 1 wherein said high k dielectric layer is etched at a rate that is more than about ten times the etch rate of said gate electrode under the same conditions.

18. The method of claim 1 further comprised of a wet clean step after the plasma etch through the high k dielectric layer is complete.

19. The method of claim 1 further comprised of forming a spacer on opposite sides of said gate electrode before etching through said high k dielectric layer.

20. A method of forming a MOSFET, comprising:
(a) providing a substrate having shallow trench isolation features which separate active regions:
(b) forming a high k dielectric layer on said substrate;
(c) depositing a gate layer on said high k dielectric layer and etching through said gate layer to form a gate electrode and expose portions of said high k dielectric layer, said gate electrode is aligned over an active region; and
(d) etching through exposed portions of said high k dielectric layer with a plasma etch comprised of an inert gas, BCl₃, and one or more fluorocarbon gases or CH₄.

21. The method of claim 20 wherein step (d) is further comprised of a low bias power of about 10 to 50 Watts.

22. The method of claim 20 wherein said high k dielectric layer is formed by a CVD, MOCVD, or ALD process and has a thickness between about 15 and 100 Angstroms.

23. The method of claim 20 wherein said high k dielectric layer is comprised of one or more of HfO₂, ZrO₂, Ta₂O₅, TiO₂, Al₂O₃, Y₂O₃ or La₂O₅.

24. The method of claim 20 wherein said high k dielectric layer is a silicate, aluminate, nitride, or oxynitride of Hf, Zr, Ta, Ti, Y, or La.

25. The method of claim 20 wherein the high k dielectric layer is subjected to a post-deposition surface treatment or an anneal step prior to forming a gate layer on said high k dielectric layer.

26. The method of claim 25 wherein said anneal step is comprised of heating the substrate in an O₂ or H₂ ambient at about 800° C. for a period of about 20 minutes.

27. The method of claim 20 wherein said gate layer is comprised of polysilicon, amorphous silicon, Si—Ge, W, Ta, Al, Ti, Ni, Ru, Pa, Pt, Mo, TiN, TaN, or TaSiN.

28. The method of claim 20 wherein said gate layer has a thickness between about 500 and 1500 Angstroms.

29. The method of claim 20 wherein said etching through exposed portions of said high k dielectric layer is performed with BCl3, an inert gas comprised of Ar, He, Ne, or Xe, and one or more C_{X}H_{Y}F_{Z} gases where x and z are integers and y is an integer or is 0 including CF₄, CHF₃, CH₂F₂, CH₃F, C₂HF₅, C₂H₂F₄, and C₂F₆.

30. The method of claim 20 wherein said etching through exposed portions of said high k dielectric layer is performed with a BCl₃ flow rate of about 100 to 400 sccm, a fluorocarbon gas flow rate from about 5 to 20 sccm, and an inert gas flow rate between about 100 and 500 sccm.

31. The method of claim 20 wherein said etching through exposed portions of said high k dielectric layer is performed with a chamber pressure from about 5 to 20 mTorr and a substrate temperature between about 50° C. and 70° C.

32. The method of claim 20 wherein said etching through exposed portions of said high k dielectric layer is performed with a RF power between about 200 and 800 Watts.

33. The method of claim 20 wherein said etching through exposed portions of said high k dielectric layer is continued until an end point is reached as indicated by a drop in an OES signal for a metal in the high k dielectric layer or is carried out for a period of about 60 to 90 seconds.

34. The method of claim 20 further comprised of forming an interfacial layer comprised of silicon nitride, SiO₂, or silicon oxynitride on said substrate prior to forming said high k dielectric layer.

35. The method of claim 34 wherein said interfacial layer is removed by the same plasma etch that etches through exposed portions of said high k dielectric layer.

36. The method of claim 20 wherein etching through exposed portions of said high k dielectric layer is performed in the same etch chamber as etching through the gate layer.

37. The method of claim 20 wherein said etching through exposed portions of said high k dielectric layer is performed at a rate that is more than about ten times the etch rate of said gate electrode under the same conditions.

38. The method of claim 20 further comprised of a wet clean step after etching through exposed portions of said high k dielectric layer is complete.

39. The method of claim 20 further comprised of forming a spacer on opposite sides of said gate electrode before etching through exposed portions of said high k dielectric layer.

40. The method of claim 20 further comprised of forming source/drain regions in said substrate and forming a silicide layer on the gate electrode and on source/drain regions in said substrate.
